(19) United States
(12) Patent Application Publication
(10) Pub. No.: US 2025/0297159 A1
(43) Pub. Date: Sep. 25, 2025

(54) ETCHING COMPOSITIONS

(71) Applicant: Fujifilm Electronic Materials U.S.A., Inc., N. Kingstown, RI (US)

(72) Inventor: Dmitry Dinega, Mesa, AZ (US)

(21) Appl. No.: 19/080,992

(22) Filed: Mar. 17, 2025

Related U.S. Application Data
(60) Provisional application No. 63/567,960, filed on Mar. 21, 2024.

(51) Int. Cl. C09K 13/02; H01L 21/02; H01L 21/311

(52) U.S. Cl. CPC C09K 13/02; H01L 21/0206; H01L 21/31111

(57) ABSTRACT

The present disclosure is directed to etching compositions that are useful for, e.g., selectively removing sacrificial light absorbing material (SLAM) from a semiconductor substrate as an intermediate step in a multistep semiconductor manufacturing process.

### CROSS-REFERENCE TO RELATED APPLICATION

The present application claims priority to U.S. Provisional Application Ser. No. 63/567,960, filed on Mar. 21, 2024, the contents of which are hereby incorporated by reference in their entirety.

### FIELD OF THE DISCLOSURE

The present disclosure relates to etching compositions and processes of using etching compositions. In particular, the present disclosure relates to etching compositions that can selectively etch sacrificial light absorbing materials (SLAM) in the presence of other exposed or underlying materials, such as metal conductors (e.g., copper), barrier materials (TIN, SiOC, TaN), or insulator materials (e.g., SiOx, low-k dielectric materials).

### BACKGROUND OF THE DISCLOSURE

In the manufacture of high-performance integrated circuits, dual damascene processes are used to create the multi-level architecture needed for these devices. Typically, sacrificial light absorbing material (SLAM) is used during lithography steps to minimize defects when building multi-level microchip architecture. While SLAM has proven useful in this regard, it needs to be removed prior to final chip preparation and packaging.

### SUMMARY OF THE DISCLOSURE

The present disclosure relates to compositions and methods for selectively etching sacrificial light absorbing material.

In some embodiments, the disclosure features compositions including at least one polar aprotic organic solvent; at least one quaternary ammonium hydroxide; at least one inorganic base; at least one compound bearing at least one sulfur atom-containing moiety; and water.

In some embodiments, the polar aprotic organic solvent includes dimethyl sulfoxide, sulfolane, dimethylsulfone, N,N-dimethylformamide, N,N-dimethylacetamide, N-methylpyrrolidone, gamma-butyrolactone, propylene carbonate, or 1,3-dimethyl-2-imidazolidinone. In some embodiments, the polar aprotic organic solvent is dimethyl sulfoxide. In some embodiments, the polar aprotic organic solvent is in an amount of from about 20 wt % to about 60 wt % of the composition. In some embodiments, mixtures of two or more solvents can be used in the compositions of the disclosure.

In some embodiments, the quaternary ammonium hydroxide is tetramethylammonium hydroxide, tetraethylammonium hydroxide, or tetrabutylammonium hydroxide. In some embodiments, the quaternary ammonium hydroxide is tetramethylammonium hydroxide. In some embodiments, the quaternary ammonium hydroxide is in an amount of from about 5 wt % to about 15 wt % of the composition.

In some embodiments, the inorganic base comprises an alkali base or alkaline earth base. In some embodiments, the inorganic base is potassium hydroxide. In some embodiments, the inorganic base is in an amount of from about 0.1 wt % to about 0.5 wt % of the composition.

In some embodiments, the compound bearing at least one sulfur atom-containing moiety is a mercapto-azole or a mercapto alcohol. In some embodiments, the compound bearing at least one sulfur atom-containing moiety is 1,2,4-triazole-3-thiol, thioglycerol, or 2-mercaptobenzimidazole. In some embodiments, the compound bearing at least one sulfur atom-containing moiety is in an amount of from about 0.1 wt % to about 0.5 wt % of the composition.

In some embodiments, the water is in an amount of from about 40 wt % to about 70 wt % of the composition.

In some embodiments, the composition has a pH from about 13 to about 14.

In some embodiments of the disclosure there are provided methods, including contacting a semiconductor substrate containing sacrificial light absorbing material with a composition of the disclosure to substantially remove the sacrificial light absorbing material. In some embodiments, the method does not substantially remove silicon oxide or low-K dielectric material (ILD).

In some embodiments of the disclosure there are provided articles formed by the methods of the disclosure, wherein the article is a semiconductor device. In some embodiments, the semiconductor device is an integrated circuit.

### DETAILED DESCRIPTION OF THE DISCLOSURE

As defined herein, unless otherwise noted, all percentages expressed should be understood to be percentages by weight to the total weight of the composition. Unless otherwise noted, ambient temperature is defined to be from about 16 to about 27 degrees Celsius (° C.). As used herein, the terms “layer” and “film” are used interchangeably.

In general, the disclosure features an etching composition (e.g., an etching composition for selectively removing sacrificial light absorbing material (SLAM)) that includes (e.g., comprises or consists of) at least one quaternary ammonium hydroxide, at least one polar aprotic organic solvent, at least one inorganic base, at least one compound bearing at least one sulfur atom-containing moiety, and water. In some embodiments, the etching composition contains these five types of components only.

In some embodiments, the etching composition of this disclosure can include at least one (e.g., two, three, or four) quaternary ammonium hydroxide. The quaternary ammonium hydroxide described herein can be a tetraalkylammonium hydroxide. In some embodiments, each alkyl group in the tetraalkylammonium hydroxide, independently, is a C₁-C₁₈ alkyl optionally substituted by OH, or an alkyl group in the tetraalkylammonium hydroxide can be substituted by an aryl group (e.g., phenyl). Examples of suitable tetraalkylammonium hydroxides or a salt thereof include tetramethylammonium hydroxide (TMAH), tetraethylammonium hydroxide, tetrapropylammonium hydroxide, tetrabutylammonium hydroxide, benzyltrimethylammonium hydroxide (BTMAH), methyltriethylammonium hydroxide, ethyltrimethylammonium hydroxide (ETMAH), dimethyldiethylammonium hydroxide, 2-hydroxyethyltrimethylammonium hydroxide, tetraethanolammonium hydroxide, benzyltriethylammonium hydroxide, benzyltributylammonium hydroxide, or hexadecyltrimethylammonium hydroxide.

In some embodiments, the at least one quaternary ammonium hydroxide is in an amount of at least about 1 wt % (e.g., at least about 2 wt %, at least about 3 wt %, at least about 4 wt %, at least about 5 wt %, at least about 6 wt %, at least about 7 wt %, or at least about 8 wt %) to at most about 15 wt % (e.g., at most about 14 wt %, at most about 12 wt %, at most about 10 wt %, at most about 8 wt %, at most about 7 wt %, at most about 6 wt %, or at most about 5 wt %) of the etching composition of this disclosure. Without wishing to be bound by theory, it is believed that the quaternary ammonium hydroxide can facilitate and enhance the removal of SLAM layers on a semiconductor substrate during the etching process.

In some embodiments, the etching composition of this disclosure can include at least one (e.g., two, three, or four) compound bearing at least one sulfur atom-containing moiety. In some embodiments, the compound bearing at least one sulfur atom-containing moiety is a mercapto-azole or a mercapto alcohol. Examples of compounds bearing at least one sulfur atom-containing moiety include, but are not limited to, 1,2,4-triazole-3-thiol, thioglycerol, L-cysteine, mercaptoethanol, or 2-mercaptobenzimidazole.

In some embodiments, the at least one compound bearing at least one sulfur atom-containing moiety can be from at least about 0.1 wt % (e.g., at least about 0.2 wt %, at least about 0.3 wt %, at least about 0.4 wt %, at least about 0.5 wt %, at least about 0.6 wt %, at least about 0.7 wt %, at least about 0.8 wt %, at least about 0.9 wt %, or at least about 1 wt %) to at most about 5 wt % (e.g., at most about 4.5 wt %, at most about 4 wt %, at most about 3.5 wt %, at most about 3 wt %, at most about 2.5 wt %, at most about 2 wt %, at most about 1.5 wt %, at most about 1 wt %, at most about 0.9 wt %, at most about 0.8 wt %, at most about 0.7 wt %, at most about 0.6 wt %, or at most about 0.5 wt %) of the etching composition of this disclosure. Without wishing to be bound by theory, it is believed that the compound bearing at least one sulfur atom-containing moiety can provide good protection of Cu lines.

In some embodiments, the inorganic base comprises an alkali base or alkaline earth base. In some embodiments, the inorganic base is potassium hydroxide. In some embodiments, the inorganic base is in an amount of from about 0.1 wt % (e.g., at least about 0.2 wt %, at least about 0.3 wt %, at least about 0.4 wt %, at least about 0.5 wt %, at least about 0.6 wt %, at least about 0.7 wt %, at least about 0.8 wt %, at least about 0.9 wt %, or at least about 1 wt %) to at most about 5 wt % (e.g., at most about 4.5 wt %, at most about 4 wt %, at most about 3.5 wt %, at most about 3 wt %, at most about 2.5 wt %, at most about 2 wt %, at most about 1.5 wt %, at most about 1 wt %, at most about 0.9 wt %, at most about 0.8 wt %, at most about 0.7 wt %, at most about 0.6 wt %, or at most about 0.5 wt %) of the etching composition of this disclosure.

In general, the etching composition of this disclosure can include water as a solvent. In some embodiments, the water can be de-ionized and ultra-pure, contain no organic contaminants, and/or have a minimum resistivity of about 4 to about 17 mega Ohms or at least about 17 mega Ohms. In some embodiments, the water is in an amount of from at least about 40 wt % (e.g., at least about 42 wt %, at least about 44 wt %, at least about 46 wt %, at least about 48 wt %, at least about 50 wt %, at least about 51 wt %, or at least about 52 wt %) to at most about 70 wt % (e.g., at most about 68 wt %, at most about 66 wt %, at most about 64 wt %, at most about 62 wt %, at most about 60 wt %, at most about 56 wt %, or at most about 54 wt %) of the etching composition.

Without wishing to be bound by theory, it is believed that, if the amount of water is greater than 70 wt % of the composition, it would adversely impact the SLAM etch rate, and reduce its removal during the etching process. On the other hand, without wishing to be bound by theory, it is believed that the etching composition of this disclosure should include a certain level of water (e.g., at least about 50 wt %) to avoid reduction in the etching performance.

In some embodiments, the etching composition of this disclosure can include at least one (e.g., two, three, or four) water soluble organic solvent. As defined herein, a “water soluble” substance (e.g., a water soluble organic solvent) refers to a substance having a solubility of at least 1% by weight in water at 25° C. In some embodiments, the organic solvent can be a polar aprotic solvent. As used herein, the term “polar aprotic solvent” refers to a solvent that lacks an acidic proton and has a relatively high dipole moment (e.g., at least 2.7). The water soluble polar aprotic organic solvent can be one water soluble solvent or a mixture of water soluble solvents in any ratio. Examples of such solvents suitable for use in the present disclosure include, but are not limited to, dimethyl sulfoxide, sulfolane, dimethylsulfone, N,N-dimethylformamide, N,N-dimethylacetamide, N-methylpyrrolidone, gamma-butyrolactone, 3-methoxy-3-methyl-1-butanol (MMB), 1,3-dimethyl-2-imidazolidinone and mixtures thereof. In some embodiments, the water soluble polar aprotic organic solvent is dimethyl sulfoxide, sulfolane, gamma-butyrolactone, or N-methylpyrrolidone.

In some embodiments, the at least one organic solvent can be from at least about 20 wt % (e.g., at least about 25 wt %, at least about 30 wt %, at least about 35 wt %, or at least about 40 wt %) to at most about 50 wt % (e.g., at most about 45 wt % or at most about 40 wt %) of the etching composition.

In some embodiments, the etching composition of this disclosure can have a pH of at least about 13 (e.g., at least about 13.1, at least about 13.2, at least about 13.3, at least about 13.4, or at least about 13.5) and/or at most about 14 (e.g., at most about 13.9, at most about 13.8, at most about 13.7, at most about 13.6, or at most about 13.5). Without wishing to be bound by theory, it is believed that an etching composition having a pH lower than 13 would not have a sufficient SLAM removal rate.

In some embodiments, the etching composition of the present disclosure can contain additives such as pH adjusting agents, corrosion inhibitors, surfactants, additional organic solvents, biocides, and defoaming agents as optional components. Examples of certain suitable additives include alcohols (e.g., polyvinyl alcohol and sugar alcohols). Examples of suitable defoaming agents include polysiloxane defoamers (e.g., polydimethylsiloxane), polyethylene glycol methyl ether polymers, ethylene oxide/propylene oxide copolymers, and glycidyl ether capped acetylenic diol ethoxylates (such as those described in U.S. Pat. No. 6,717,019, herein incorporated by reference). Examples of suitable surfactants can be cationic, anionic, nonionic, and amphoteric surfactants.

Suitable bases that can be used as a pH adjusting agent include monoamines (including alkanolamines), and cyclic amines. Examples of suitable monoamines include, but are not limited to, triethylamine, tributylamine, tripentylamine, diethylamine, butylamine, dibutylamine, and benzylamine. Examples of suitable alkanolamines include, but are not limited to, monoethanolamine, diethanolamine, triethanolamine, and aminopropyldiethanolamine. Examples of suitable cyclic amines include, but are not limited to, 1,8-diazabicyclo [5.4.0]-7-undecene (DBU), 1,5-diazabicyclo [4.3.0]-5-nonene (DBN), and octahydro-2H-quinolizine.

In general, the etching compositions of the present disclosure can have a relatively high SLAM removal while causing minimal damage to Cu lines and other dielectric materials present on a device (e.g., ILD, SiOx, or SiCO, TIN, TaN) (i.e., a high ratio of SLAM removal rate over metal and dielectric material removal rate). In addition, the compositions remove dry etch residue that can be present on the device in a form of fluorinated compounds. In some embodiments, the etching composition can have a SLAM removal rate selectivity of at least about 10 (e.g., at least about 20, at least about 40, at least about 50, at least about 60, at least about 80, at least about 100, at least about 150, at least about 200, at least about 250, at least about 300, at least about 350, at least about 400, at least about 450, at least about 500, or at least about 1000) and/or at most about 5000 (e.g., at most about 4000, at most about 3000, at most about 2000, or at most about 1000).

In some embodiments, the etching compositions of the present disclosure can be substantially free of one or more of additive components, in any combination, if more than one. Such components are selected from the group consisting of organic solvents, polymers (e.g., non-ionic, cationic, or anionic polymers), oxygen scavengers, quaternary ammonium compounds (e.g., salts or hydroxides), alkaline bases (such as NaOH, KOH, LiOH, Mg(OH)₂, and Ca(OH)₂), surfactants (e.g., cationic, anionic, or non-ionic surfactants), defoamers, fluorine-containing compounds (e.g., fluoride compounds or fluorinated compounds (such as fluorinated polymers/surfactants)), silicon-containing compounds such as silanes (e.g., alkoxysilanes), nitrogen-containing compounds (e.g., amino acids, amines, imines (e.g., amidines such as 1,8-diazabicyclo [5.4.0]-7-undecene (DBU) and 1,5-diazabicyclo[4.3.0]non-5-ene (DBN)), amides, or imides), abrasives (e.g., ceria abrasives, non-ionic abrasives, surface modified abrasives, negatively/positively charged abrasives, or ceramic abrasive composites), plasticizers, oxidizing agents (e.g., peroxides such as hydrogen peroxide, and periodic acid), corrosion inhibitors (e.g., azole or non-azole corrosion inhibitors), electrolytes (e.g., polyelectrolytes), silicates, cyclic compounds (e.g., azoles (such as diazoles, triazoles, or tetrazoles), triazines, and cyclic compounds containing at least two rings such as substituted or unsubstituted naphthalenes, or substituted or unsubstituted biphenylethers), chelating agents, buffering agents, acids such as organic acids (e.g., organosulfonic acids, carboxylic acids such as hydroxycarboxylic acids or polycarboxylic acids) and inorganic acids (e.g., sulfuric acid, sulfurous acid, nitrous acid, nitric acid, phosphorous acid, and phosphoric acid), salts (e.g., halide salts or metal salts), and catalysts (e.g., metal-containing catalysts). In some embodiments, the composition is substantially free of a salt other than a quaternary ammonium salt. As used herein, a component that is “substantially free” from an etching composition refers to an ingredient that is not intentionally added into the etching composition. In some embodiments, the etching composition described herein can have at most about 1000 ppm (e.g., at most about 500 ppm, at most about 250 ppm, at most about 100 ppm, at most about 50 ppm, at most about 10 ppm, or at most about 1 ppm) of one or more of the above components that are substantially free from the etching composition. In some embodiments, the etching compositions described herein can be completely free of one or more of the above components.

The etching composition of this disclosure can be prepared by simply mixing the components together, or can be prepared by blending two or more compositions (each containing certain components of an etching composition described herein) in a kit.

In some embodiments, the present disclosure features a method of etching a semiconductor substrate that includes a SLAM film. The method can include contacting a semiconductor substrate containing the SLAM film with an etching composition of this disclosure to substantially remove the SLAM film. In some embodiments, the semiconductor substrate can include a pattern or a feature on a surface and the SLAM film is a part of the pattern or feature. In some embodiments, the method can further include rinsing the semiconductor substrate with a rinse solvent after the contacting step and/or drying the semiconductor substrate after the rinsing step.

In some embodiments, the method does not substantially remove metal conductor (Cu) or dielectric material (e.g., ILD, SiOx, or SiCO, TIN, TaN) in the semiconductor substrate. In some embodiments, the dielectric material is silicon oxide or silicon nitride. For example, the method does not remove more than about 5% by weight (e.g., more than about 3% by weight or more than about 1% by weight) of a metal conductor or a dielectric material in the semiconductor substrate.

In some embodiments, the etching method includes the steps of:
A) providing a semiconductor substrate containing a SLAM film (e.g., a SLAM film in a pattern or feature);
(B) contacting the semiconductor substrate with an etching composition described herein;
(C) rinsing the semiconductor substrate with one or more suitable rinse solvents; and
(D) optionally, drying the semiconductor substrate (e.g., by any suitable means that removes the rinse solvent and does not compromise the integrity of the semiconductor substrate).

The semiconductor substrates to be etched in this method can contain dry etch residue in a form of fluorinated compounds that also need be removed during the etching process.

Semiconductor substrates described herein (e.g., wafers) typically are constructed of silicon, silicon germanium, Group III-V compounds such as GaAs, or any combination thereof. The semiconductor substrates can additionally contain exposed integrated circuit structures such as interconnect features (e.g., metal lines and dielectric materials). Metals and metal alloys used for interconnect features include, but are not limited to, aluminum, aluminum alloyed with copper, copper, titanium, tantalum, cobalt, silicon, titanium nitride, tantalum nitride, and tungsten. The semiconductor substrates can also contain layers of interlayer dielectrics, polysilicon, silicon oxide, silicon nitride, silicon germanium, silicon carbide, titanium oxide, and carbon doped silicon oxides.

A semiconductor substrate can be contacted with the etching composition by any suitable method, such as placing the etching composition into a tank and immersing and/or submerging the semiconductor substrate into the etching composition, spraying the etching composition onto the semiconductor substrate, streaming the etching composition onto the semiconductor substrate, or any combinations thereof.

The etching composition of the present disclosure can be effectively used up to a temperature of about 60° C. (e.g., from about 40° C. to about 60° C., or from about 45° C. to about 55° C.). The etch rates of SLAM increase with temperature in this range, thus the processes at a higher temperature can be run for shorter times. Conversely, lower etching temperatures typically require longer etching times.

Etching times can vary over a wide range depending on the particular etching method, thickness, and temperature employed. When etching in an immersion batch type process, a suitable time range is, for example, up to about 5 minutes (e.g., from about 1 minute to about 4 minutes, or from about 1 minute to about 3 minutes). Etching times for a single wafer process can range from about 20 seconds to about 4 minutes.

To further promote the etching ability of the etching composition of the present disclosure, mechanical agitation means can be employed. Examples of suitable agitation means include circulation of the etching composition over the substrate, streaming or spraying the etching composition over the substrate, and ultrasonic or megasonic agitation during the etching process. The orientation of the semiconductor substrate relative to the ground can be at any angle. Horizontal or vertical orientations are preferred.

Subsequent to the etching, the semiconductor substrate can be rinsed with a suitable rinse solvent for about 5 seconds up to about 5 minutes with or without agitation means. Multiple rinse steps employing different rinse solvents can be employed. Examples of suitable rinse solvents include, but are not limited to, deionized (DI) water, methanol, ethanol, isopropyl alcohol, N-methylpyrrolidinone, gamma-butyrolactone, dimethyl sulfoxide, ethyl lactate, and propylene glycol monomethyl ether acetate. Alternatively, or in addition, aqueous rinses with pH>8 (such as dilute aqueous ammonium hydroxide) can be employed. The rinse solvent can be applied using means similar to that used in applying an etching composition described herein. The etching composition may have been removed from the semiconductor substrate prior to the start of the rinsing step or it may still be in contact with the semiconductor substrate at the start of the rinsing step. In some embodiments, the temperature employed in the rinsing step is from 16° C. to 27° C.

Optionally, the semiconductor substrate is dried after the rinsing step. Any suitable drying means known in the art can be employed. Examples of suitable drying means include spin drying, flowing a dry gas across the semiconductor substrate, or heating the semiconductor substrate with a heating means such as a hotplate or infrared lamp, Maragoni drying, rotagoni drying, IPA drying, and any combinations thereof. Drying times will be dependent on the specific method employed but are typically on the order of 30 seconds up to several minutes.

In some embodiments, concentrates of the compositions of the disclosure are contemplated for use. Concentrates can be, for example, 2× (i.e., double the concentration of components in the composition) or 3× (i.e., triple the concentration of components in the composition) The concentrates are diluted to 1:1 with DIW prior to use. Concentrates are useful in proving cost reductions.

In some embodiments, the compositions of the disclosure include at least one Group II metal cation. Examples of suitable Group II metal cations include Ca²+Mg²+, Sr²+, and Ba²+. In some embodiments, the at least one Group II metal cation includes Ca²+. In some embodiments, the compositions described herein can include the Group II metal cation in an amount of at least about 1 ppm (e.g., at least about 3 ppm, at least about 5 ppm, or at least about 7 ppm) and/or at most about 40 ppm (e.g., at most about 35 ppm, at most about 25 ppm, at most about 20 ppm, or at most about 15 ppm).

In some embodiments, the compositions of the disclosure can also include at least one metal cation complexing agent. In some embodiments, the at least one metal cation complexing agent is a carboxylic acid. In some embodiments, the compositions of the disclosure can include at least one carboxylic acid. Without wishing to be bound by theory, it is believed that carboxylic acids can improve the solubility of Group II metal cations in the compositions of the disclosure. In some embodiments, examples of the at least one carboxylic acid contemplated for use in the compositions of the disclosure include, but are not limited to, monocarboxylic acids, bicarboxylic acids, tricarboxylic acids, α-hydroxyacids and beta-hydroxyacids of monocarboxylic acids, alpha-hydroxyacids or beta-hydroxyacids of bicarboxylic acids, or alpha-hydroxyacids and beta-hydroxyacids of tricarboxylic acids. In some embodiments, the at least one carboxylic acid includes citric acid, maleic acid, fumaric acid, lactic acid, glycolic acid, oxalic acid, tartaric acid, succinic acid, or benzoic acid. In some embodiments, the carboxylic acid is citric acid.

In some embodiments of the disclosure there are provided articles formed by the methods of the disclosure, wherein the article is a semiconductor device. In some embodiments, the semiconductor device is an integrated circuit. In some embodiments, the etching method described herein further includes forming a semiconductor device (e.g., an integrated circuit device such as a semiconductor chip) from the semiconductor substrate obtained by the method described above.

### EXAMPLES

### General Procedure 1

### Formulation Blending

Samples of etching compositions were prepared by adding, while stirring, to the calculated amount of the solvent the remaining components of the formulation.

### General Procedure 2

### Materials and Methods

Blanket film etch rate measurements on films were carried out using Unpatterned 300 mm diameter wafers with blanket films diced into 0.5″×1.0″ test coupons for evaluation. Blanket film materials used for testing include 1) a SiOC film of 1700 Å deposited on Si substrate; 2) an ILD film having a thickness of about 6000 Å deposited on SiOC layer of 1700 Å deposited on a silicon substrate, 3) SLAM film having a thickness of about 1600 Å, deposited on ILD film of about 6000 Å, deposited on a SiOC film of about 1700 Å, deposited on a silicon substrate; 4) a TiN film having a thickness of about 130 Å deposited on a silicon substrate, and 5) a SiOx film having a thickness of about 1100 Å deposited on a silicon substrate.

The blanket film test coupons were measured for pre-treatment and post-treatment thickness to determine blanket film etch rates. For the SLAM, ILD, SiOC, TIN and SiOx blanket films, the film thicknesses were measured pre-treatment and post-treatment by Ellipsometry using a Woollam VASE.

### General Procedure 3

### Etching Evaluation with Beaker Test

All blanket film etch testing was carried out in a 150 mL PFA bottle containing 100 g of a sample solution with continuous stirring at 250 rpm. The PFA bottle was immersed into a 600 mL glass beaker filled with water serving as a water bath. The beaker was sitting on the top of a hot stirring plate set at the desired temperature. All blanket test coupons having a blanket film exposed on one side to the sample solution were diced by diamond scribe into 0.5″×1.0″ square test coupon size for beaker scale testing. Each individual test coupon was held into position using a single 4″ long, locking plastic tweezers clip. The test coupon, held on one edge by the locking tweezers clip, was suspended into the 150 mL PFA bottle and immersed into the 100 g test solution while the solution was stirred continuously at 250 rpm at 45° C. or 55° C. The test coupons were held static in the stirred solution until complete SLAM removal (15-50 sec). All other etch rates were calculated based on 20 minutes treatment time.

After the treatment time in the test solution had elapsed, the sample coupons were immediately removed from the 150 mL PFA bottle and rinsed. Specifically, the coupon was immersed in a 300 mL volume of ultra-high purity deionized (DI) water for 15 seconds with mild agitation, which was followed by immersion in 300 mL of isopropyl alcohol (IPA) for 15 seconds with mild agitation, and a final rinse by immersion in 300 mL of IPA for 15 seconds with mild agitation. After the final IPA rinse step, all test coupons were subject to a filtered nitrogen gas blow off step using a hand held nitrogen gas blower which forcefully removed all traces of IPA to produce a final dry sample for test measurements.

### Example 1

Formulation Examples 1-6 (FE-1 to FE-6) were prepared according to General Procedure 1, and evaluated according to General Procedures 2 and 3. The formulations and their test results are summarized in Table 1. All the etch rates (ERs) in this table were measured at 45° C. All compositions of the disclosure exhibited good SLAM removal with minimal removal of other layers.

TABLE 1

| | | | | | | | | SLAM | TiN | SiOx | SiOC | ILD | Cu |
|---|---|---|---|---|---|---|---|---|---|---|---|---|---|
| | | | | | | | | removal | ER | ER | ER | ER | ER, |
| Formulation | TMAH | KOH | DMSO | Sulfur compound | Water | Total | pH | time | (Å/min) | (Å/min) | (Å/min) | (Å/min) | (Å/min) |
| FE-1 | 10% | 0.15% | 45% | 2% thioglycerol | 42.85% | 100% | 13.4 | + | 0.04 | 1.0 | 0.29 | 4.0 | 1.3 |
| FE-2 | 12% | 0.32% | 37% | 1.4% 1,2,4-triazole-3- | 49.28% | 100% | 13.6 | +++ | 0.07 | 1.8 | 0.20 | 5.0 | 1.8 |
| | | | | thiol | | | | | | | | | |
| FE-3 | 12% | 0.32% | 35% | 0.5% 1,2,4-triazole-3- | 52.03% | 100% | 13.6 | +++ | 0.06 | 0.8 | 0.20 | 6.2 | 1.2 |
| | | | | thiol; 0.15% 2- | | | | | | | | | |
| | | | | mercaptobenzimidazole | | | | | | | | | |
| FE-4 | 12% | 0.32% | 30% | 0.5% 1,2,4-triazole-3- | 57.03% | 100% | 13.6 | ++ | 0.05 | 0.7 | 0.23 | 5.3 | 1.35 |
| | | | | thiol; 0.15% 2- | | | | | | | | | |
| | | | | mercaptobenzimidazole | | | | | | | | | |
| FE-5 | 12% | 0.32% | 26% | 0.5% 1,2,4-triazole-3- | 61.03% | 100% | 13.55 | + | 0.05 | 0.6 | 0.26 | 4.6 | 2.6 |
| | | | | thiol; 0.15% 2- | | | | | | | | | |
| | | | | mercaptobenzimidazole | | | | | | | | | |
| FE-6 | 12% | .30% | 35% | 0.5% 1,2,4-triazole-3- | 52.19% | 100% | 13.6 | +++ | 0.07 | 0.8 | 0.23 | 5.2 | 1.1 |
| | | | | thiol; citric acid- | | | | | | | | | |
| | | | | 0.0125%; calcium | | | | | | | | | |
| | | | | citrate tetrahydrate- | | | | | | | | | |
| | | | | 0.0002% | | | | | | | | | |

SLAM removal times:
+—good;
++—faster;
+++—fastest

While the invention has been described in detail with reference to certain embodiments thereof, it will be understood that modifications and variations are within the spirit and scope of that which is described and claimed.

What is claimed is:

1. A composition, comprising:
at least one polar aprotic organic solvent;
at least one quaternary ammonium hydroxide;
at least one inorganic base;
at least one compound bearing at least one sulfur atom-containing moiety; and
water.

2. The composition of claim 1, wherein the polar aprotic organic solvent comprises dimethyl sulfoxide, sulfolane, dimethylsulfone, N,N-dimethylformamide, N,N-dimethylacetamide, N-methylpyrrolidone, gamma-butyrolactone, propylene carbonate, or 1,3-dimethyl-2-imidazolidinone.

3. The composition of claim 1, wherein the polar aprotic organic solvent comprises dimethyl sulfoxide.

4. The composition of claim 1, wherein the polar aprotic organic solvent is in an amount of from about 20 wt % to about 60 wt % of the composition.

5. The composition of claim 1, wherein the quaternary ammonium hydroxide comprises tetramethylammonium hydroxide, tetraethylammonium hydroxide, or tetrabutylammonium hydroxide.

6. The composition of claim 1, wherein the quaternary ammonium hydroxide comprises tetramethylammonium hydroxide.

7. The composition of claim 1, wherein the quaternary ammonium hydroxide is in an amount of from about 5 wt % to about 15 wt % of the composition.

8. The composition of claim 1, wherein the inorganic base comprises an alkali base or alkaline earth base.

9. The composition of claim 1, wherein the inorganic base comprises potassium hydroxide.

10. The composition of claim 1, wherein the inorganic base is in an amount of from about 0.1 wt % to about 0.5 wt % of the composition.

11. The composition of claim 1, wherein the compound bearing at least one sulfur atom-containing moiety is a mercapto-azole or a mercapto alcohol.

12. The composition of claim 1, wherein the compound bearing at least one sulfur atom-containing moiety is 1,2,4-triazole-3-thiol, thioglycerol, or 2-mercaptobenzimidazole.

13. The composition of claim 1, wherein the compound bearing at least one sulfur atom-containing moiety is in an amount of from about 0.1 wt % to about 0.5 wt % of the composition.

14. The composition of claim 1, wherein the water is in an amount of from about 40 wt % to about 70 wt % of the composition.

15. The composition of claim 1, wherein the composition has a pH from about 13 to about 14.

16. The composition of claim 1, further comprising at least one Group II metal cation.

17. The composition of claim 16, wherein the at least one Group II metal cation comprises Ca²⁺.

18. The composition of claim 1, further comprising a metal cation complexing agent.

19. The composition of claim 18, wherein the complexing agent is a carboxylic acid.

20. The composition of claim 19, wherein the carboxylic acid comprises citric acid, maleic acid, fumaric acid, lactic acid, glycolic acid, oxalic acid, tartaric acid, succinic acid, or benzoic acid.

21. A method, comprising:
contacting a semiconductor substrate containing sacrificial light absorbing material with a composition of claim 1 to substantially remove the sacrificial light absorbing material.

22. The method of claim 21, wherein the method does not substantially remove silicon oxide or silicon nitride.

23. A method comprising:
(A) providing a semiconductor substrate containing a sacrificial light absorbing material film;
(B) contacting the semiconductor substrate with an etching composition of claim 1;
(C) rinsing the semiconductor substrate with one or more rinse solvents; and
(D) optionally, drying the semiconductor substrate.

24. An article formed by the method of claim 21, wherein the article is a semiconductor device.

25. The article of claim 24, wherein the semiconductor device is an integrated circuit.
